(19) United States
(12) Patent Application Publication
(10) Pub. No.: US 2025/0374506 A1
(43) Pub. Date: Dec. 4, 2025

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Jui-Lin Chen, Taipei City (TW); Jung-Piao Chiu, Kaohsiung City (TW); Kai-Yuan Cheng, Hsinchu (TW)

(21) Appl. No.: 18/883,320

(22) Filed: Sep. 12, 2024

Related U.S. Application Data
(60) Provisional application No. 63/655,656, filed on Jun. 4, 2024.

(51) Int. Cl. H10B 10/00

(52) U.S. Cl. CPC H10B 10/125

(57) ABSTRACT

In an embodiment, a method of manufacturing a semiconductor device includes forming a multi-layer stack over a substrate, the multi-layer stack comprising alternating layers of first semiconductor layers and second semiconductor layers, forming a first PMOS pull down transistor, the forming the first PMOS pull down transistor including removing the first semiconductor layers in a first region of the substrate, forming a disposable material between the second semiconductor layers in the first region, forming source/drain regions adjacent the second semiconductor layers and the disposable material in the first region, and replacing the disposable material in the first region with a first metal gate structure, and forming a first NMOS pull up transistor, the forming the first NMOS pull up transistor comprising replacing the first semiconductor layers in a second region of the substrate with a second metal gate structure.

### PRIORITY CLAIM AND CROSS-REFERENCE

This application claims the benefit of U.S. Provisional Application No. 63/655,656, filed on Jun. 4, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an example of a nanostructure field-effect transistor (nano-FET) in a three-dimensional view, in accordance with some embodiments.

FIG. 1B illustrates a circuit diagram of a first memory cell that can be formed using the nano-FETs discussed in FIG. 1A, in accordance with some embodiments.

FIGS. 2, 3, 4, 5, 6A, 6B, 7A, 7B 8A, 8B, 9A, 9B, 10A, 10B, 11A, 11B, 12A, 12B, 13A, 13B, 13C, 14A, 14B, 14C, 14D, 15A, 15B, 15C, 16A, 16B, 17A, 17B, 18A, 18B, 19A, 19B, 20A, 20B, 20C, 21A, 21B, 21C, 22A, 22B, and 22C are cross-sectional views of intermediate stages in the manufacturing of nano-FETs, in accordance with some embodiments.

FIGS. 23A, 23B, and 23C are cross-sectional views of a nano-FET, in accordance with some embodiments.

FIG. 24 illustrates a top down view of first SRAM device, in accordance with some embodiments.

FIGS. 25A-25B illustrate NMOS and PMOS devices that are formed with disposable material, in accordance with some embodiments.

FIGS. 26A-26B illustrate floating bottom isolations, in accordance with some embodiments.

FIGS. 27A-27B illustrate an STI cap layer, in accordance with some embodiments.

FIG. 28 illustrates an embodiment with an STI cap layer and floating bottom isolations, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to semiconductor devices and methods for enhancing performance and reducing defects, particularly in the context of nanostructure field-effect transistors (nano-FETs) used to form six transistor static random access memory (SRAM) memory cells. As the semiconductor industry strives to increase the integration density of electronic components, the challenge of managing and improving the performance of these densely packed structures becomes increasingly complex. This disclosure introduces techniques and structures that address these challenges by utilizing a Disposable Oxide Interposer (DOI) process in the manufacture of the SRAM device.

In some embodiments, each of the transistors utilized in the disclosed SRAM device includes a substrate with nanostructures formed thereon, where the nanostructures serve as channel regions for nano-FETs. The DOI process involves the use of an oxide material, such as silicon dioxide (SiO₂), silicon oxynitride (SiON), aluminum oxide (Al₂O₃), or the like, to replace silicon germanium (SiGe) as a dummy material during the manufacturing process of one or more of the transistors in the SRAM device. This substitution is advantageous as it reduces the intermixing of silicon and germanium and eases the diffusion of germanium through the oxide/silicon interface. As a result, the transistors which utilize the DOI process retain a larger width than other transistors which may not use the DOI process.

The disclosed semiconductor device and method offer several advantages over conventional techniques. By reducing the diffusion of germanium and preventing NMG extrusion defects, the disclosed method enables the fabrication of nano-FETs with enhanced electrical characteristics, such as lower resistance and higher drive currents. Additionally, the larger silicon channel height achieved through the DOI process contributes to a reduction in channel resistance, further enhancing the performance of the semiconductor device.

Embodiments are described below in a particular context, an SRAM device comprising nano-FET transistors. Various embodiments may be applied, however, to dies comprising other types of transistors (e.g., fin field effect transistors (FinFETs), planar transistors, or the like) in combination with the nano-FETs.

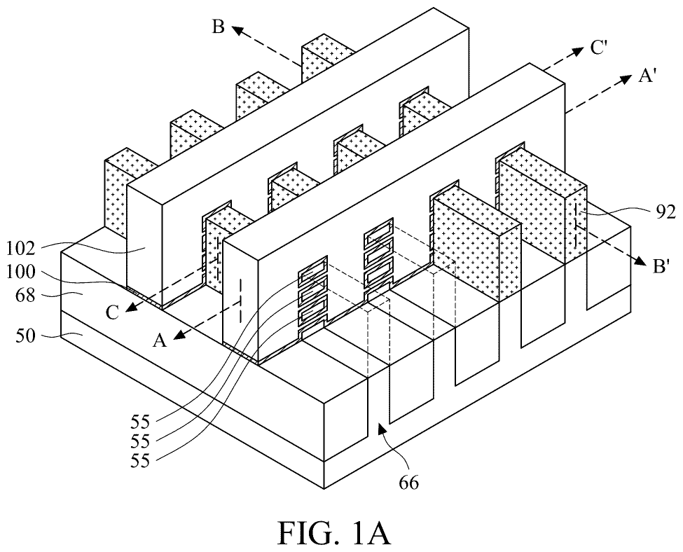

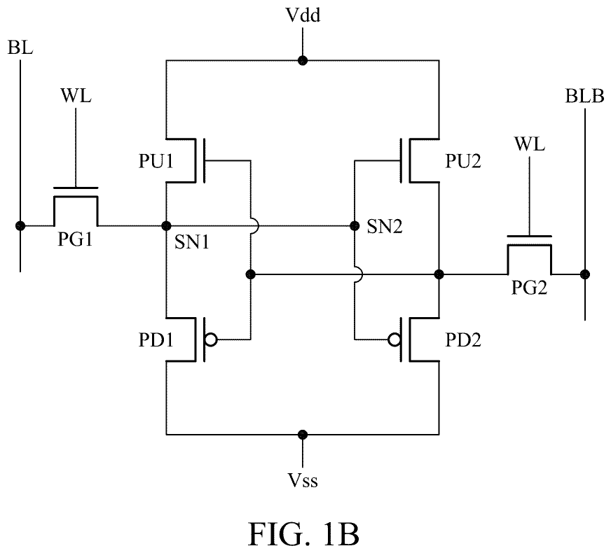

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1A further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

FIG. 1B illustrates a circuit diagram of a first memory cell that can be formed using the nano-FETs discussed in FIG. 1A, according to an embodiment. The cell includes pull-up transistors PU1 and PU2; pull-down transistors PD1 and PD2; and pass-gate transistors PG1 and PG2. As show in the circuit diagram, pull-up transistors PU1 and PU2 are n-type transistors, and pull-down transistors PD1 and PD2 and pass-gate transistors PG1 and PG2 are p-type transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary second storage node SN2. Sources of the pull-up transistors PU1 and PU2 are coupled to power voltage Vdd, and the sources of the pull-down transistors PD1 and PD2 are coupled to a ground voltage Vss.

The first storage node SN1 of the first data latch is coupled to bit line BL through pass-gate transistor PG1, and the complementary second storage node SN2 is coupled to complementary bit line BLB through pass-gate transistor PG2. The first storage node SN1 and the complementary second storage node SN2 are complementary nodes that are often at opposite logic levels (logic high or logic low). Gates of pass-gate transistors PG1 and PG2 are coupled to a word line WL.

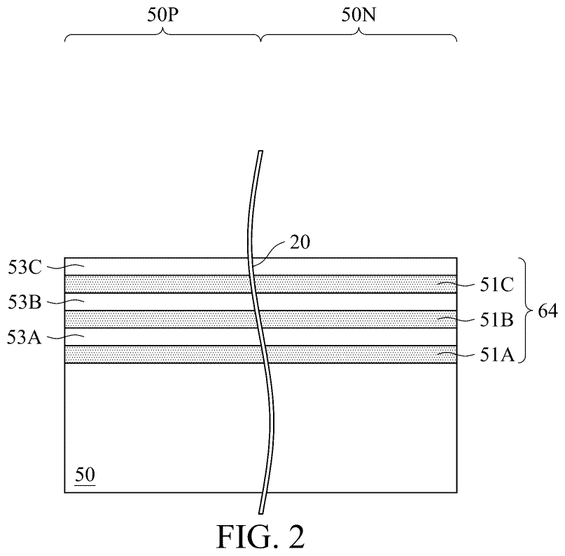

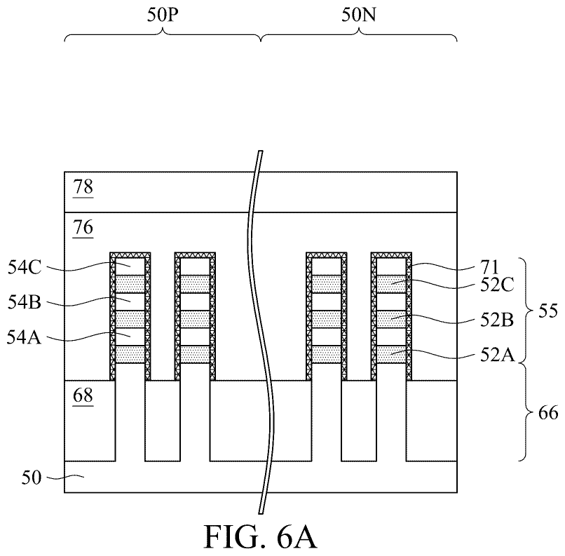

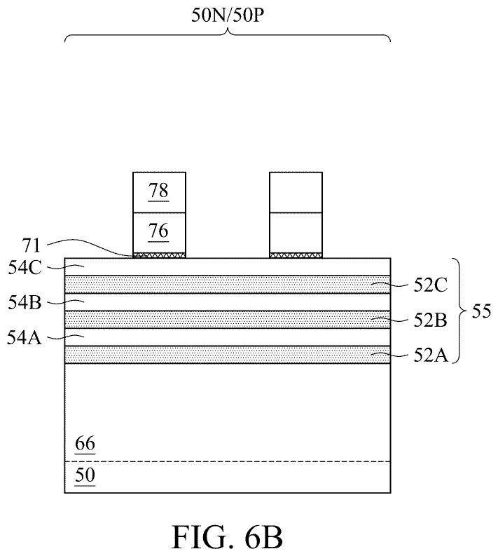

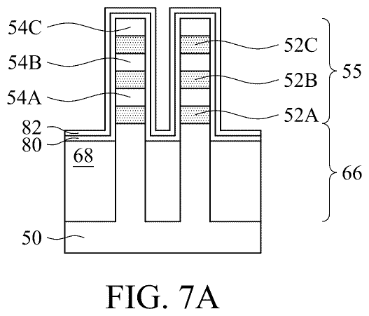

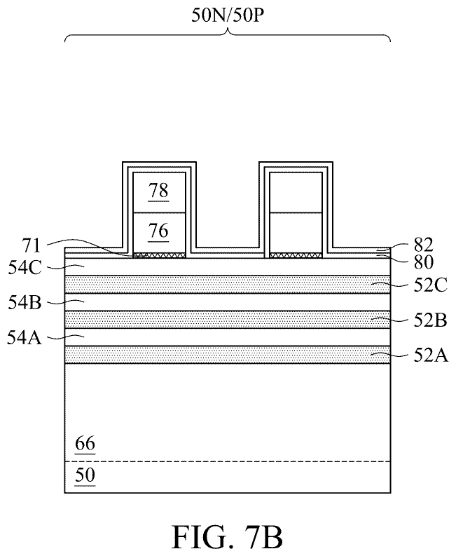

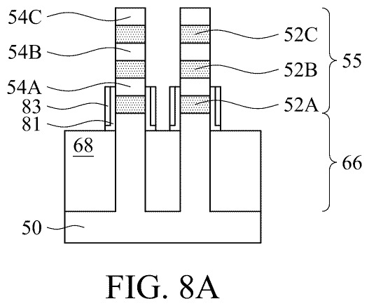

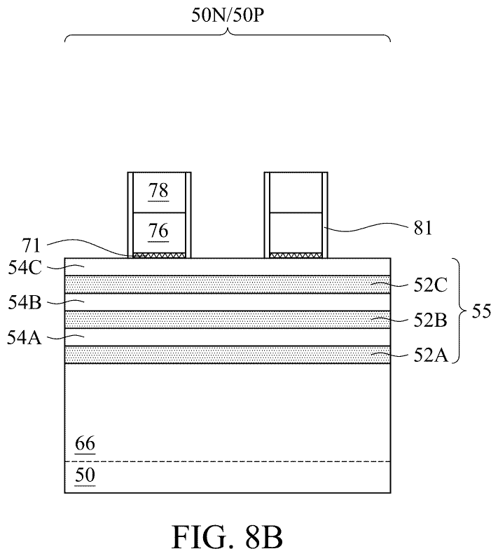

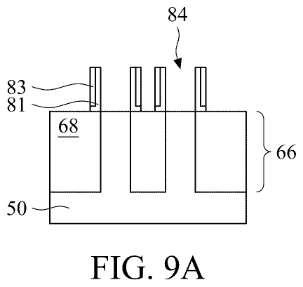

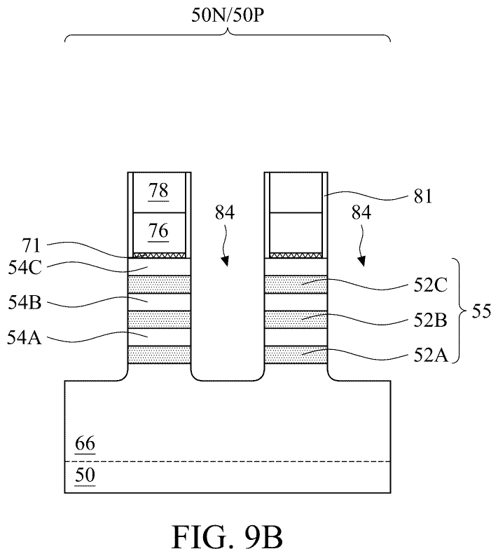

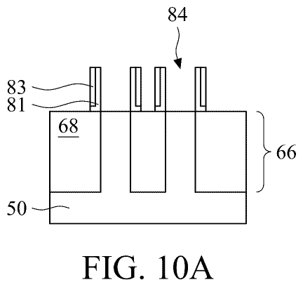

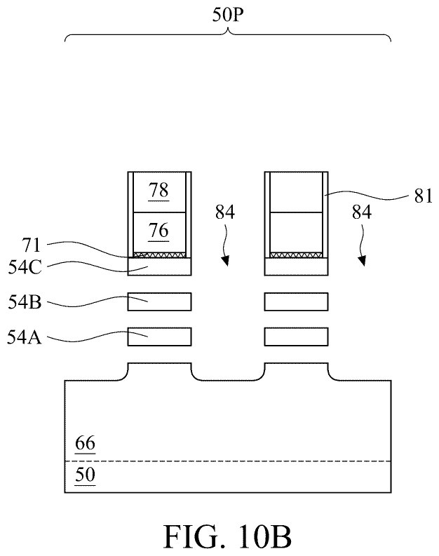

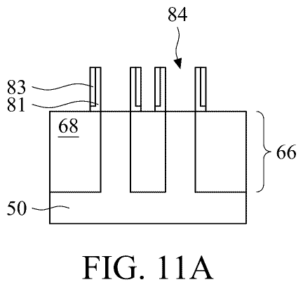

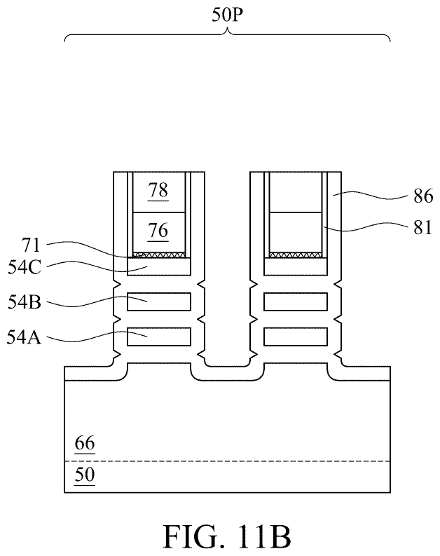

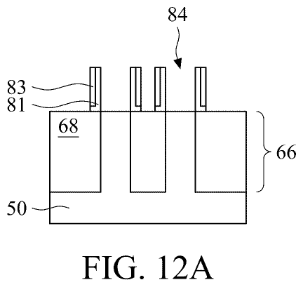

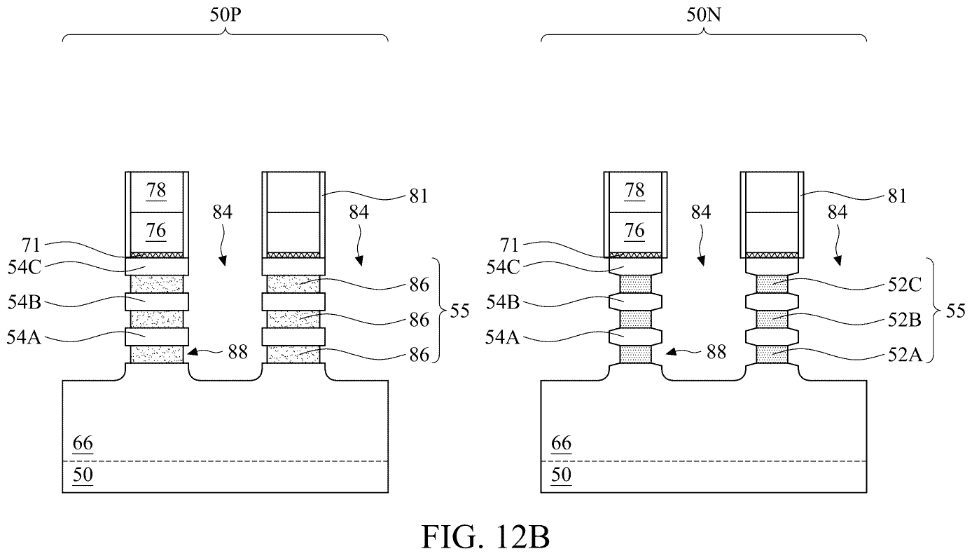

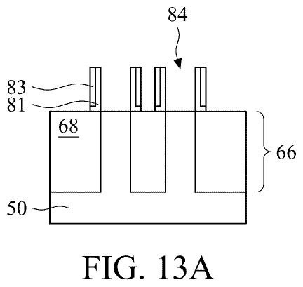

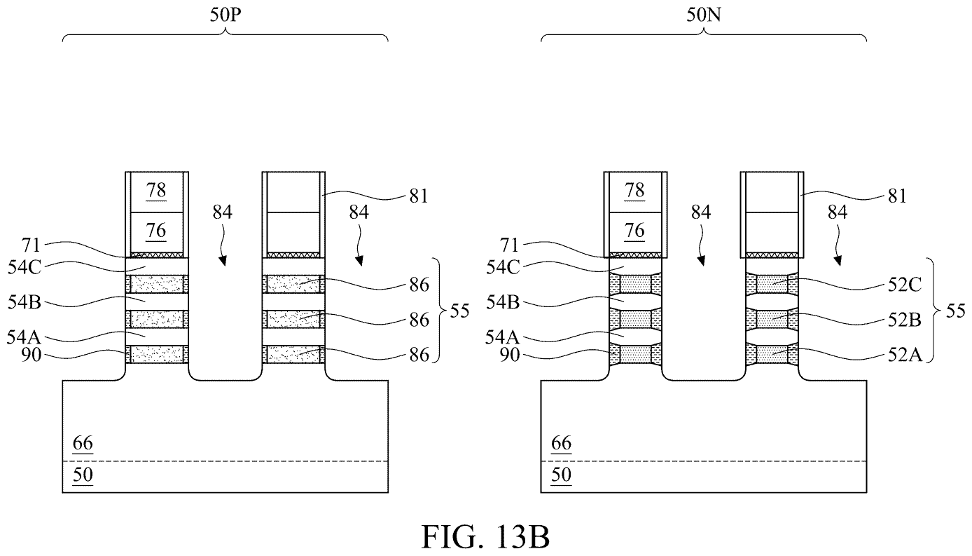

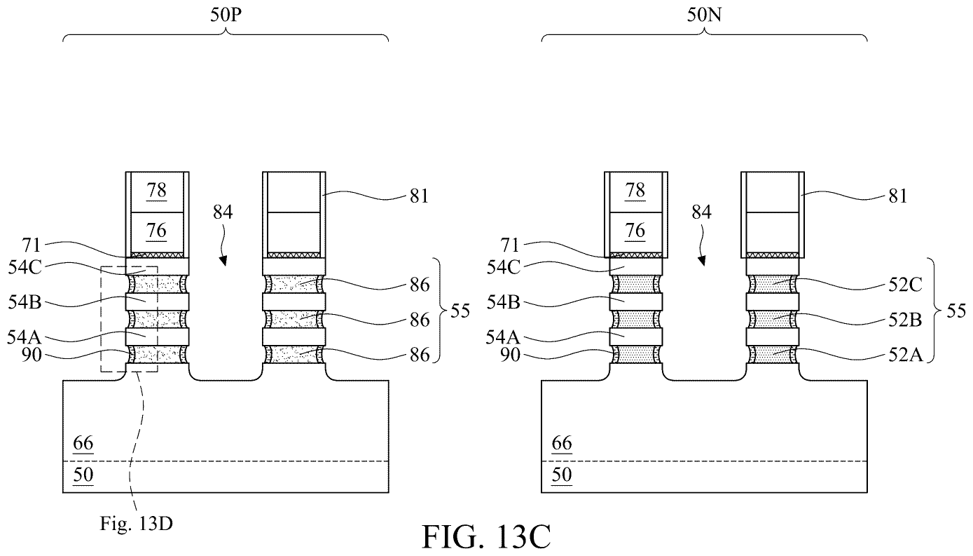

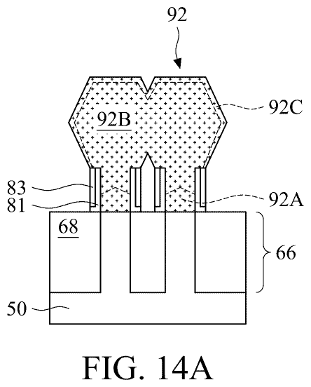

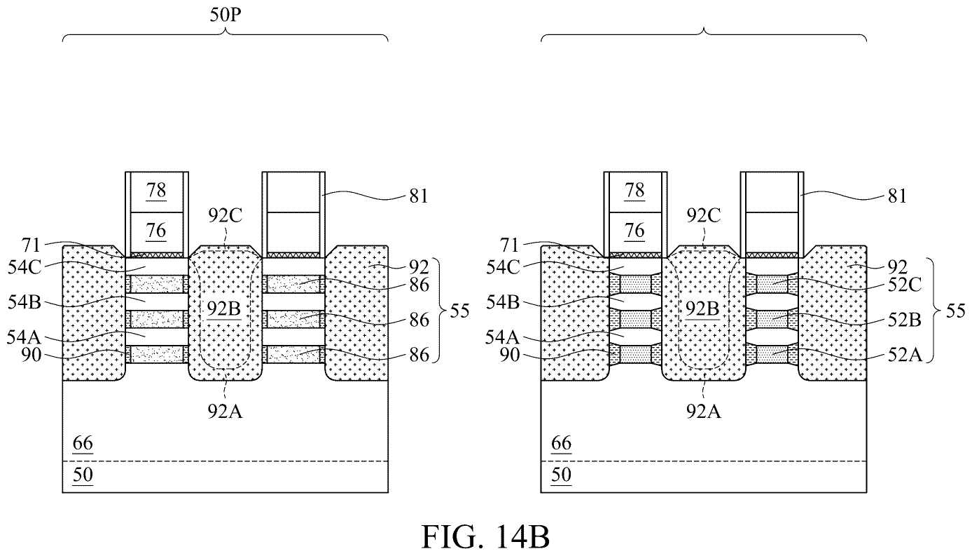

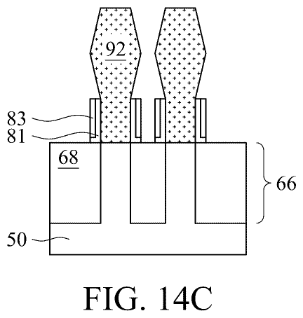

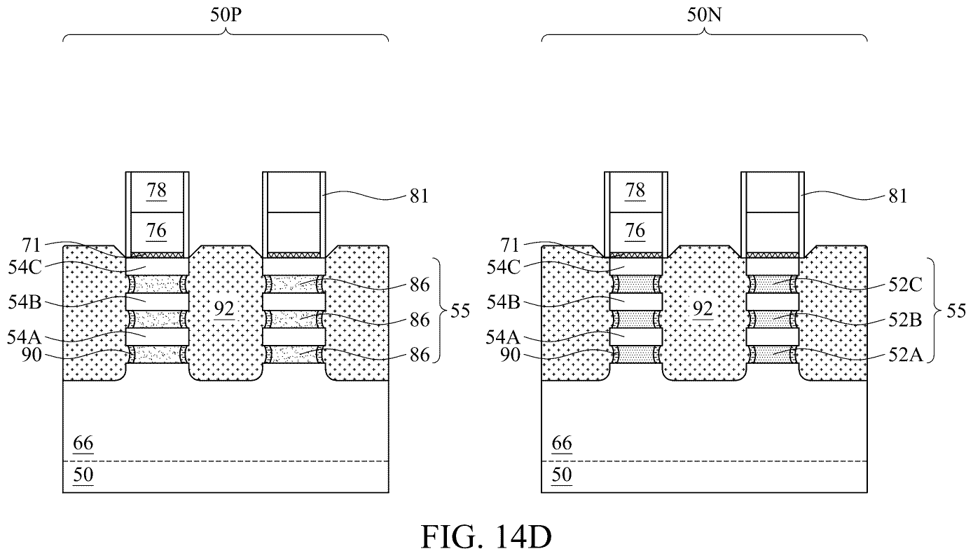

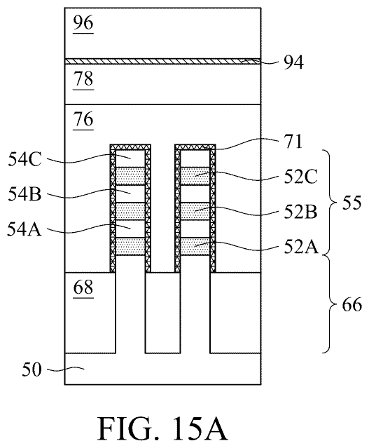

FIGS. 2 through 23C are cross-sectional views of intermediate stages in the manufacturing of nano-FETs used in the SRAM device of FIG. 1B, in accordance with some embodiments. FIGS. 2 through 5, 6A, 15A, 16A, 17A, 18A, 19A, 20A, 21A, 22A, and 23A illustrate reference cross-section A-A′ illustrated in FIG. 1A. FIGS. 6B, 7B, 8B, 9B, 10B, 11B, 11C, 12B, 12D, 13B, 14B, 15B, 16B, 17B, 18B, 19B, 20B, 21B, 22B, and 23B illustrate reference cross-section B-B′ illustrated in FIG. 1A. FIGS. 7A, 8A, 9A, 10A, 11A, 12A, 13A, 14A, 14C, 15C, 20C, 21C, 22C, and 23C illustrate reference cross-section C-C′ illustrated in FIG. 1A.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

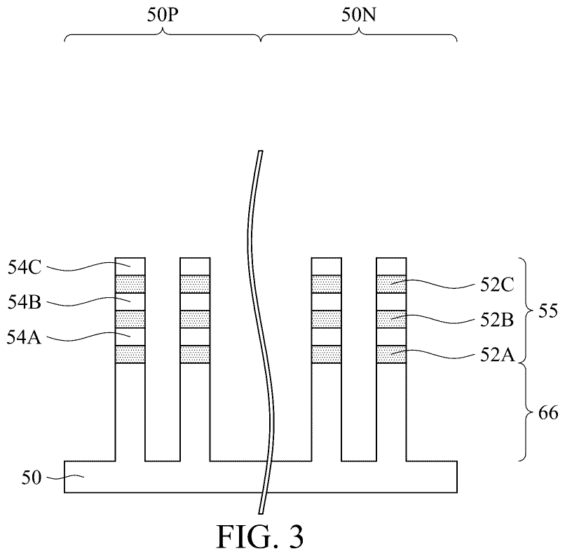

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

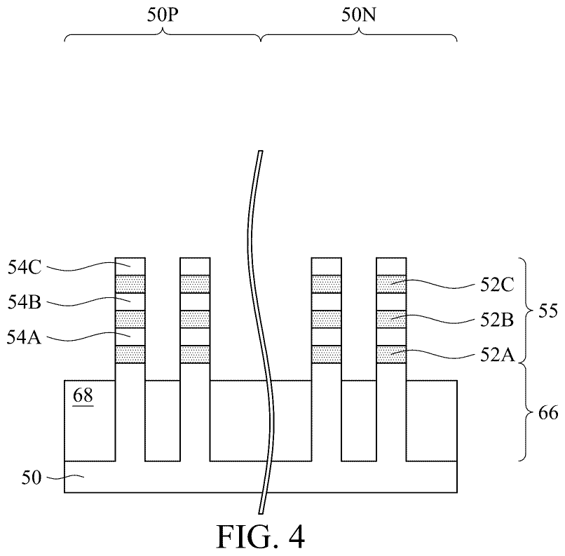

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, hydrogen fluoride, diluted hydrogen fluoride, another fluorine-based etchant, or the like may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from 10¹³ atoms/cm³ to 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from 10¹³ atoms/cm³ to 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

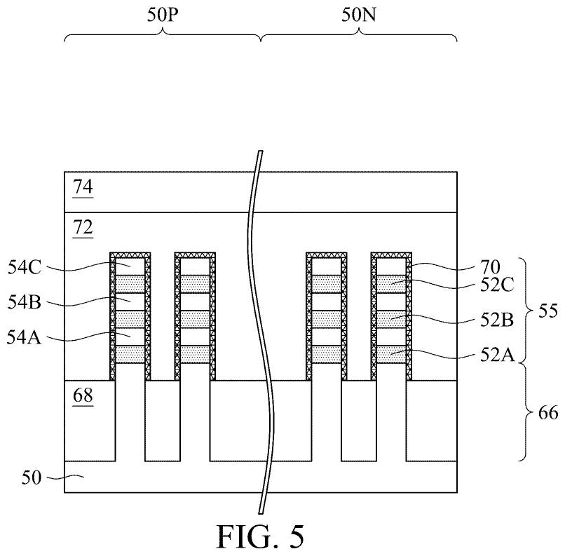

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment devices. FIGS. 6A, 6B, 7A, 7B, 8A, 8B, 9A, 9B, 10A, 11A, 12A, 12C, 13A, 13C, 14A, 14C, 15A, 15C, 16A, and 18C illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the length wise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 1×10¹⁵ atoms/cm³ to 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-align subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 84 are formed in the fins 66, the nanostructures 55, and the substrate 50, in accordance with some embodiments. Epitaxial source/drain regions will be subsequently formed in the first recesses 84. The first recesses 84 may extend through the first nanostructures 52 and the second nanostructures 54, and into the substrate 50. As illustrated in FIG. 9A, top surfaces of the STI regions 58 may be level with bottom surfaces of the first recesses 84. In various embodiments, the fins 66 may be etched such that bottom surfaces of the first recesses 84 are disposed below the top surfaces of the STI regions 68; or the like. The first recesses 84 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 84. A single etch process or multiple etch processes may be used to etch each layer of the nanostructures 55 and/or the fins 66. Timed etch processes may be used to stop the etching of the first recesses 84 after the first recesses 84 reach a desired depth.

In FIGS. 10A and 10B, the first nanostructures 52 in the p-type region 50P are removed extending the first recesses 84. The first nanostructures 52 may be removed by forming a mask (not shown) over the n-type region 50N (not separately illustrated in FIG. 10B) and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

In FIGS. 11A and 11B, a disposable material 86 is deposited in the first recesses 84 and spaces where the first nanostructures 52 were removed. The disposable material 86 may be deposited by a conformal deposition process, such as CVD, ALD, or the like. In some embodiments, the disposable material 86 may include one or more layers of material with large etch selectivity to the surrounding materials. For example, in an embodiment in which the second nanostructures 54 are silicon, the material of the disposable material 86 may be a material with an etch selectivity of greater than 100000, such as silicon dioxide (SiO₂), silicon oxynitride (SiON), aluminum oxide (Al₂O₃), or the like. These materials are selected for their properties, such as etch selectivity, which allows for precise removal during the manufacturing process without adversely affecting the adjacent and underlying silicon structures. The choice of oxide material may depend on the specific requirements of the semiconductor device being fabricated and the desired electrical and physical properties of the final product.

In FIGS. 12A and 12B, portions of sidewalls of the disposable material 86 is etched to form sidewall recesses 88 in the p-type region 50P, and portions of sidewalls of the layers of the multi-layer stack 56 formed of the first semiconductor materials (e.g., the first nanostructures 52) exposed by the first recesses 84 are etched to form sidewall recesses 88 in the n-type region 50N. Although sidewalls of the disposable material 86 and the first nanostructures 52 in sidewall recesses 88 are illustrated as being straight in FIG. 12B, the sidewalls may be concave or convex (see e.g., FIG. 13C). The etching may be isotropic or anisotropic.

For example, the n-type region 50N may be protected using a mask (not shown) while etchants selective to the disposable material 86 are used to etch the disposable material 86 such that the second nanostructures 54 and the substrate 50 remain relatively unetched as compared to the disposable material 86 in the p-type region 50P. The disposable material 86 may be etched by a wet etch process using hydrogen fluoride, diluted hydrogen fluoride, another fluorine-based etchant, or the like as an etchant. In some embodiments, the recessing is performed by repeating a dry etching and wet etching process several times. In some embodiments, the etching is performed until sidewalls of the disposable material 86 are recessed past sidewalls of the second nanostructures 54.

Similarly, the p-type region 50P may be protected using a mask (not shown) while etchants selective to the first semiconductor materials are used to etch the first nanostructures 52 such that the second nanostructures 54 and the substrate 50 remain relatively unetched (although some etching may occur) as compared to the first nanostructures 52 in the n-type region 50N. In an embodiment in which the first nanostructures 52 include, e.g., SiGe, and the second nanostructures 54 include, e.g., Si or SiC, a wet or dry etch process with tetramethylammonium hydroxide (TMAH), ammonium hydroxide (NH₄OH), or the like may be used to etch sidewalls of the first nanostructures 52 in the n-type region 50N.

However, because there is a lower etch selectivity between the materials of the first nanostructures 52 and the second nanostructures 54 in the n-type region 50N than between the second nanostructures 54 and the disposable material 86 in the p-type region 50P, the etch in the n-type region 50N results in a different shape for the recesses 88 in the n-type region 50N than the p-type region 50P. In particular, while the recesses 88 in the p-type region 50P will have flat upper and bottom surfaces, the recesses 88 in the n-type region 50N may expand up and/or down, for a more trapezoidal shape for the recesses 88 in the n-type region 50N.

Replacing the first nanostructures 52 in the p-type region 50P may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at interfaces between the nanostructures 52 and 54 may result. Such manufacturing defects may degrade the performance of the resulting transistor devices. By replacing the first nanostructures 52 with an insulating material prior to the high temperature processes (e.g., source/drain annealing), manufacturing defects can be reduced and device performance can be improved.

In FIGS. 13A-13C, first inner spacers 90 are formed in the sidewall recess 88 in both the p-type region 50P and the n-type region 50N. The first inner spacers 90 may be formed by depositing an inner spacer layer (not separately illustrated) over the structures illustrated in FIGS. 12A and 12B. The first inner spacers 90 act as isolation features between subsequently formed source/drain regions and a subsequently formed gate structure (discussed further below).

The inner spacer layer may be deposited by a conformal deposition process, such as CVD, ALD, or the like, thereby taking the shape of the recesses 88. The inner spacer layer may comprise a material such as silicon nitride or silicon oxynitride, although any suitable material, such as low-dielectric constant (low-k) materials having a k-value less than 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54. Once formed, the first inner spacers 90 have taken the shape of the sidewalls of the recesses 88, such that the first inner spacers 90 in the p-type region 50P (e.g., with the disposable material 86) have flat upper/bottom surfaces while the first inner spacers 90 in the n-type region 50N (e.g., without the disposable material 86) have expanding surfaces and have a trapezoidal shape.

Moreover, although the outer sidewalls of the first inner spacers 90 are illustrated as being straight in FIG. 13B, the outer sidewalls of the first inner spacers 90 may be concave or convex. As an example, FIG. 13C illustrates an embodiment in which sidewalls of the disposable material 86 are concave, outer sidewalls of the first inner spacers 90 are concave, and the first inner spacers 90 are recessed from sidewalls of the second nanostructures 54 in the p-type region 50P.

In FIGS. 14A-14D, epitaxial source/drain regions 92 are formed in the first recesses 84. As illustrated in FIG. 14B, the epitaxial source/drain regions 92 are formed in the first recesses 84 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 84 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets and may also, in some embodiments, have a region of undoped silicon (not separately illustrated) between the epitaxial source/drain regions 92 and the fins 66.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 84 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between 1×10¹⁹ atoms/cm³ and 1×10²¹ atoms/cm³. The n-type and/or p-type impurities for source/drain regions may be any of the impurities previously discussed. In some embodiments, the epitaxial source/drain regions 92 may be in situ doped during growth.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 14A. In other embodiments, adjacent epitaxial source/drain regions 92 remain separated after the epitaxy process is completed as illustrated by FIG. 14C. In the embodiments illustrated in FIGS. 14A and 14C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 14D illustrates an embodiment in which sidewalls of the disposable material 86 in the p-type region 50P and sidewalls of the first nanostructures 52 in the n-type region 50N are concave, outer sidewalls of the first inner spacers 90 are concave, and the first inner spacers 90 are recessed from sidewalls of the second nanostructures 54. As illustrated in FIG. 14D, the epitaxial source/drain regions 92 may be formed in contact with the first inner spacers 90 and may extend past sidewalls of the second nanostructures 54 in the p-type region 50P and the n-type region 50N.

In FIGS. 15A-15C, a first interlayer dielectric (ILD) 96 is deposited over the structure illustrated in FIGS. 6A, 14B, and 14A (the processes of FIGS. 7A-14D do not alter the cross-section illustrated in FIGS. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 16A-16B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 17A and 17B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 18A and 18B, the disposable material 86 in the p-type region 50P and the first nanostructures 52 in the n-type region 50N are removed. The disposable material 86 may be removed by forming a mask (not shown) over the n-type region 50N and performing an isotropic etching process such as wet etching or the like using etchants which are selective to the materials of the disposable material 86, while the second nanostructures 54 and the substrate 50 remain relatively unetched as compared to the disposable material 86. In embodiments in which the disposable material 86 include, e.g., SiO₂, and the second nanostructures 54A-54C include, e.g., Si or SiC, hydrogen fluoride, diluted hydrogen fluoride, another fluorine-based etchant, or the like may be used to remove the disposable material 86 in the p-type region 50P. In some embodiments, the removal of the disposable material 86 is performed by repeating a dry etching and wet etching process several times.

The first nanostructures 52 in the n-type region 50N may be removed by forming a mask (not shown) over the n-type region 50N and performing an isotropic etching process such as wet etching or the like using etchants which are selective to the materials of the first nanostructures 52, while the second nanostructures 54, the substrate 50, and the STI regions 58 remain relatively unetched as compared to the first nanostructures 52. In embodiments in which the first nanostructures 52 include, e.g., SiGe, and the second nanostructures 54 include, e.g., Si, tetramethylammonium hydroxide (TMAH), ammonium hydroxide (NH₄OH), or the like may be used to remove the first nanostructures 52 in the n-type region 50N.

In FIGS. 19A and 19B, gate dielectric layers 100 and gate electrodes 102 are formed for replacement gates. The gate dielectric layers 100 are deposited conformally in the second recesses 98. In the n-type region 50N and the p-type region 50P, the gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectric layers 100 may comprise an interfacial, silicon oxide layer and a metal oxide layer over the silicon oxide layer. In some embodiments, the gate dielectric layers 100 include a high-k dielectric material, and in these embodiments, the gate dielectric layers 100 may have a k value greater than 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 includes protection layers, such as silicon, barrier layers, such as titanium nitride, work function materials such as a metal-containing material such as titanium nitride, titanium oxide, tantalum nitride, tantalum carbide, cobalt, ruthenium, aluminum, titanium aluminum, tungsten, combinations thereof, or multi-layers thereof. For example, although single layer gate electrodes 102 are illustrated in FIGS. 19A and 19B, the gate electrodes 102 may comprise any number of liner layers, any number of work function tuning layers, and a fill material. Any combination of the layers which make up the gate electrodes 102 may be deposited in the n-type region 50N and the p-type region 50P between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

By utilizing the disposable oxide interposer (DOI) process, better device performance can be achieved. In particular, the DOI process replaces silicon germanium (SiGe) with an oxide material, which mitigates the diffusion of germanium into the silicon channel. This reduction in germanium diffusion is advantageous as it minimizes the risk of defects, which can adversely affect the electrical performance and reliability of the nano-FETs. Moreover, the higher etch selectivity of the oxide material compared to SiGe allows for a more controlled and less invasive removal process, preserving the integrity of the silicon nanostructures. Consequently, the nanostructures retain a larger height and width, contributing to a reduction in channel resistance and an enhancement in device performance. The DOI process thus enables the fabrication of nano-FETs with improved structural and electrical characteristics, leading to semiconductor devices with improved performance metrics.

Additionally, because different processes are utilized in the n-type region 50N (e.g. without the disposable material 86) and the p-type region 50P (e.g., with the disposable material 86), the structures will be different. For example, in the n-type region 50N, the first inner spacers 90 may comprise germanium residue left over from the presence of the first nanostructures 52 while the first inner spacers 90 in the p-type region 50P have a lower amount of germanium residue, or none at all, because the first nanostructures 52 have been removed prior to formation of the first inner spacers 90. Similarly, the second nanostructures 54 in the p-type region 50P with the use of the disposable material 86 can be formed with flatter and smoother surfaces than the second nanostructures 54 in the n-type region 50P.

In FIGS. 20A-20C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the contacts 114, discussed below with respect to FIGS. 22A-22C) penetrate through the gate mask 104 to contact the top surface of the recessed gate electrodes 102.

As further illustrated by FIGS. 20A-20C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 21A-21C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 21B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between 2 nm and 10 nm.

Next, in FIGS. 22A-22C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

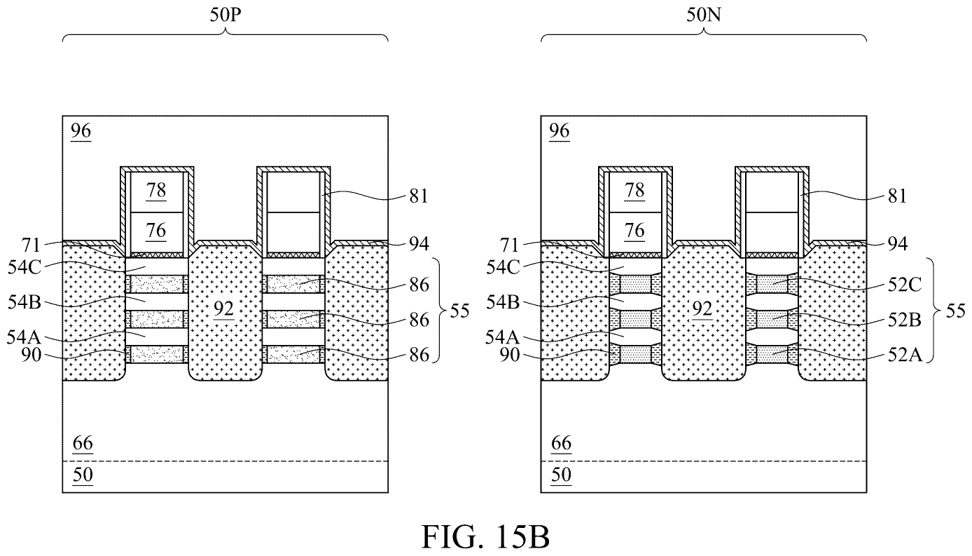

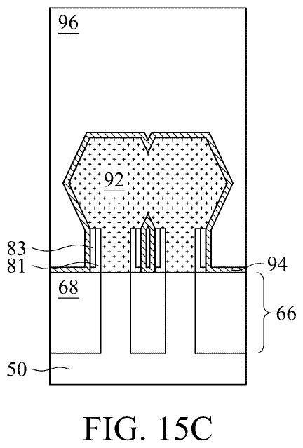

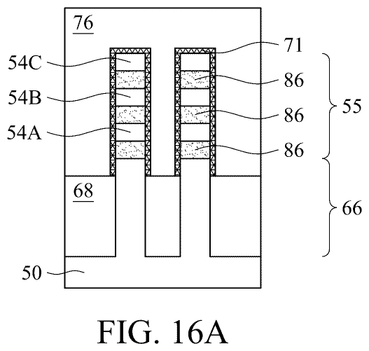

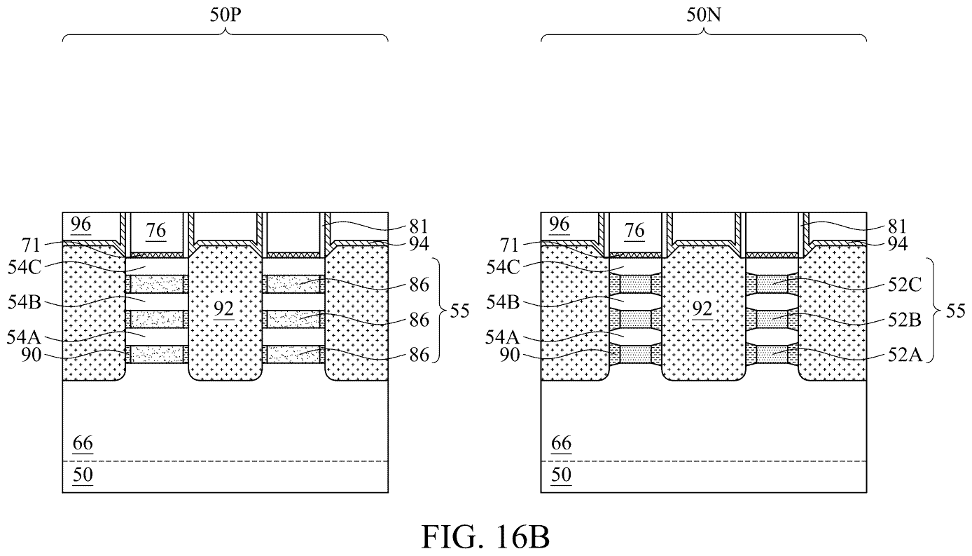

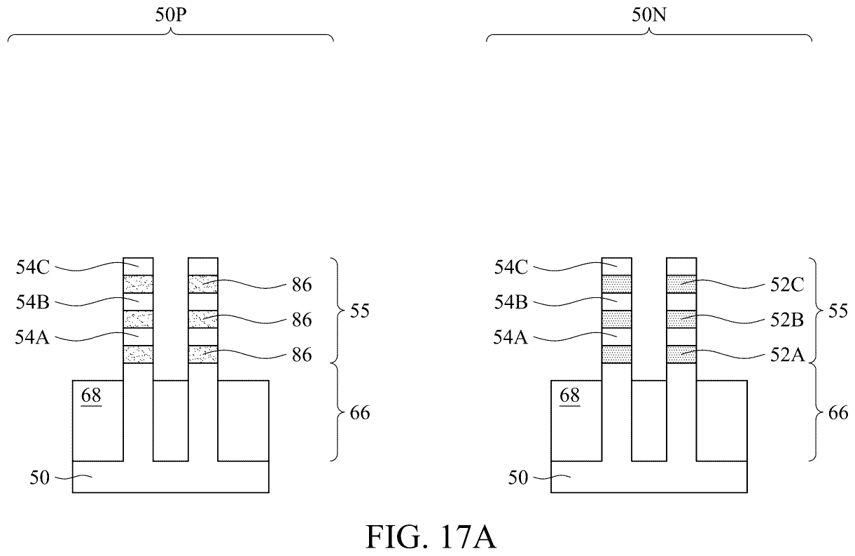

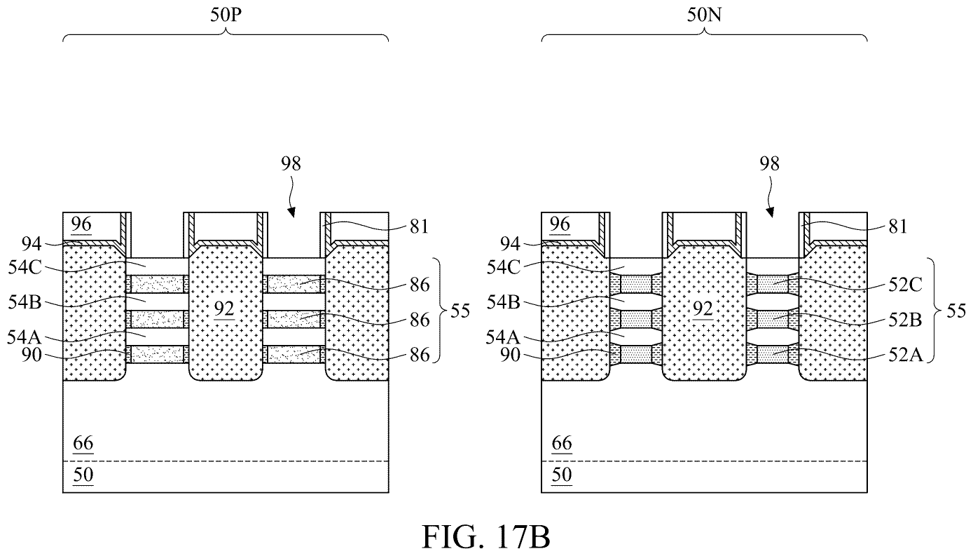

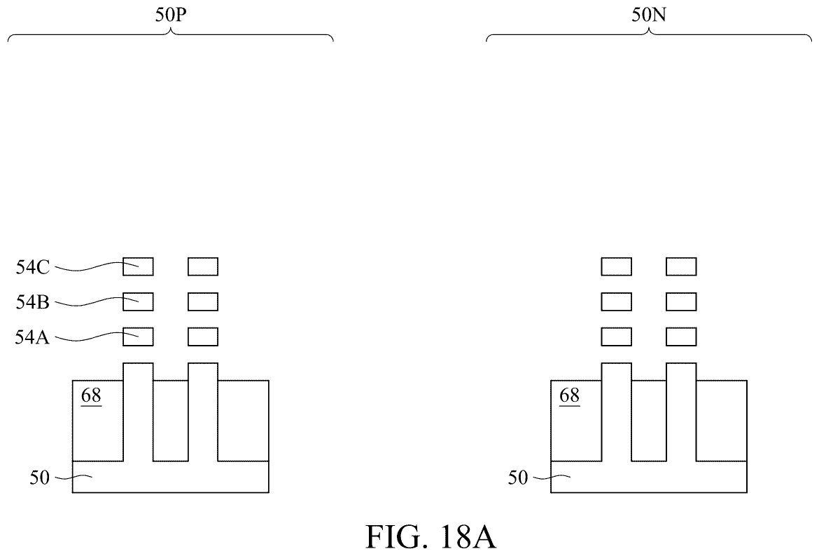

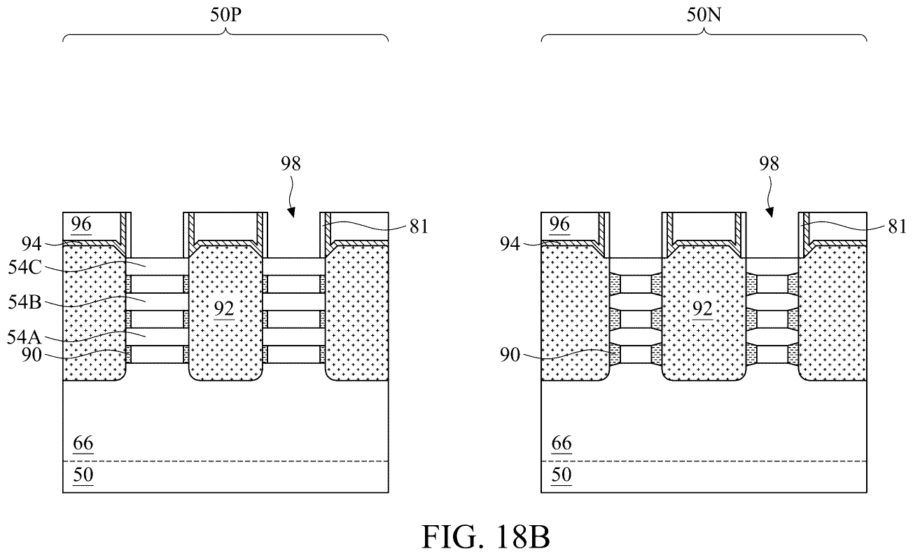

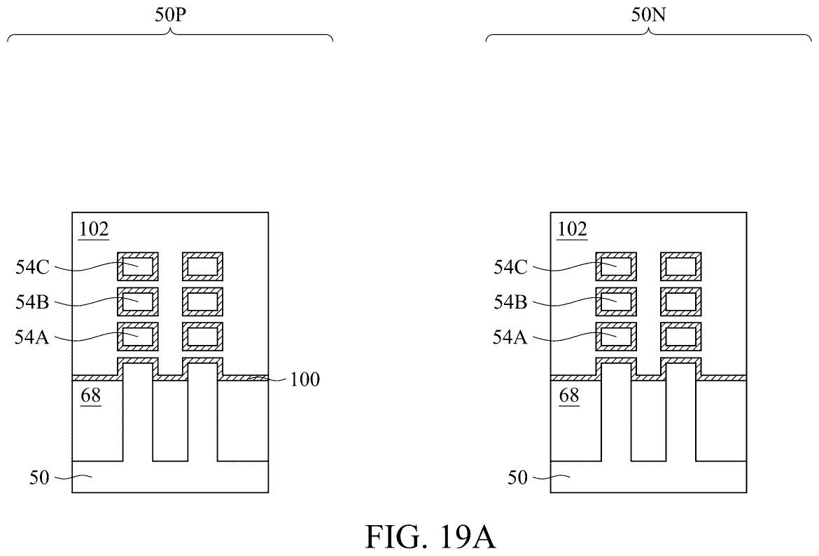

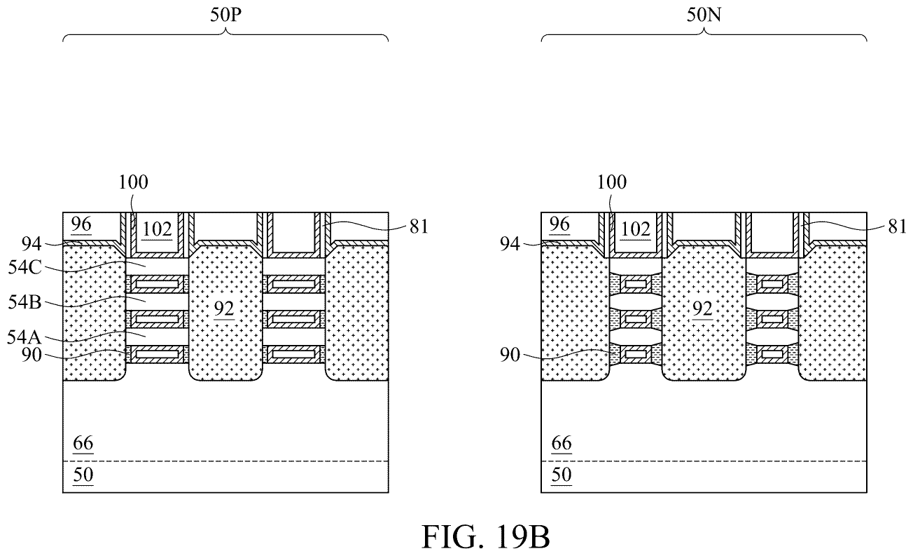

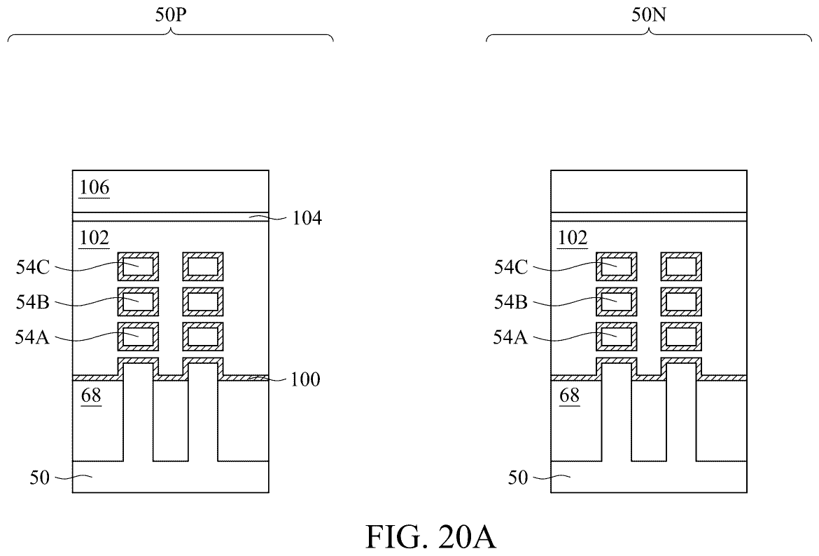

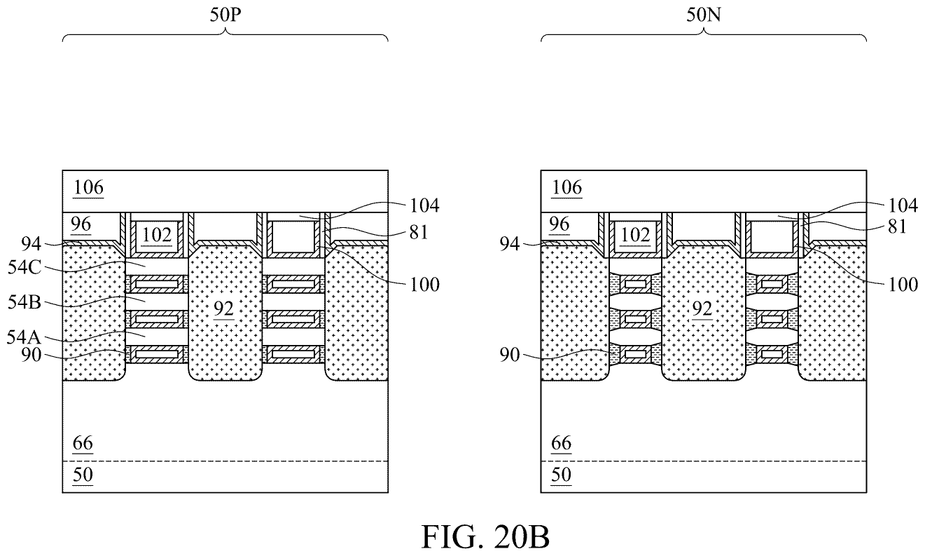

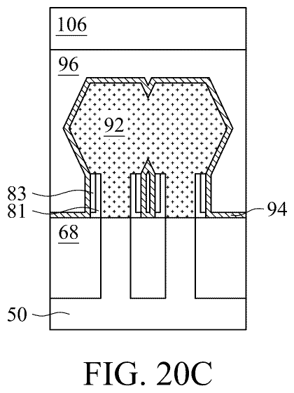

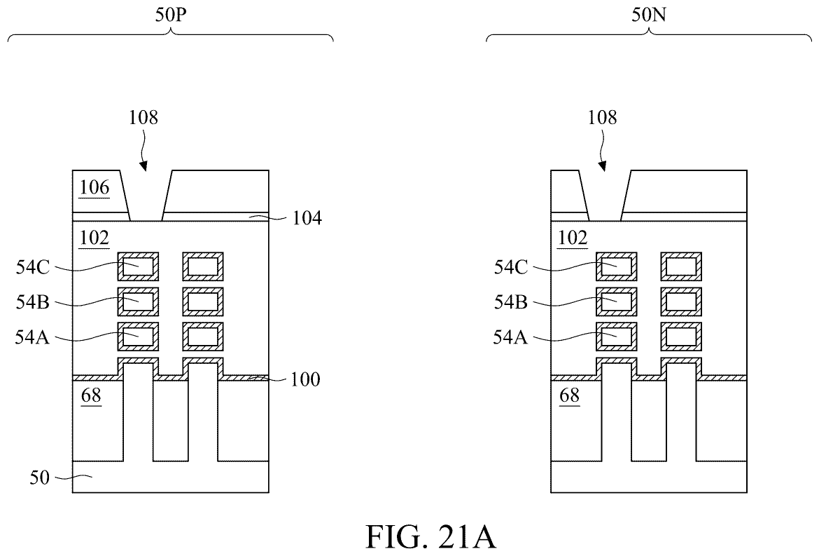

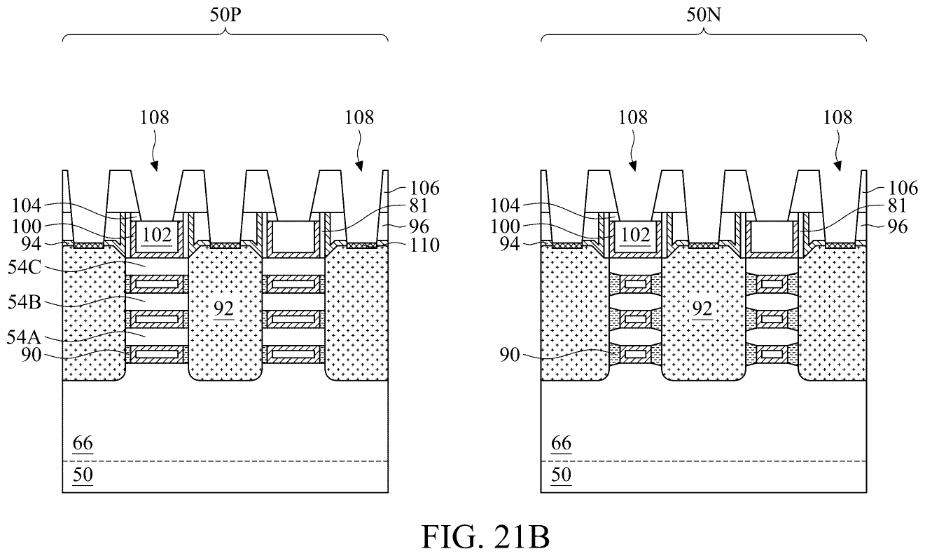

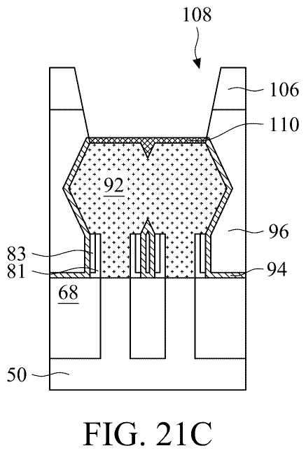

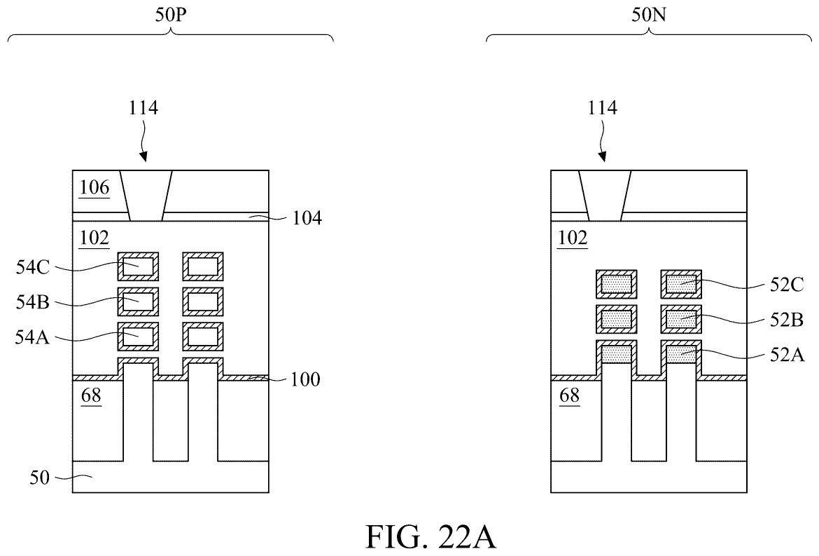

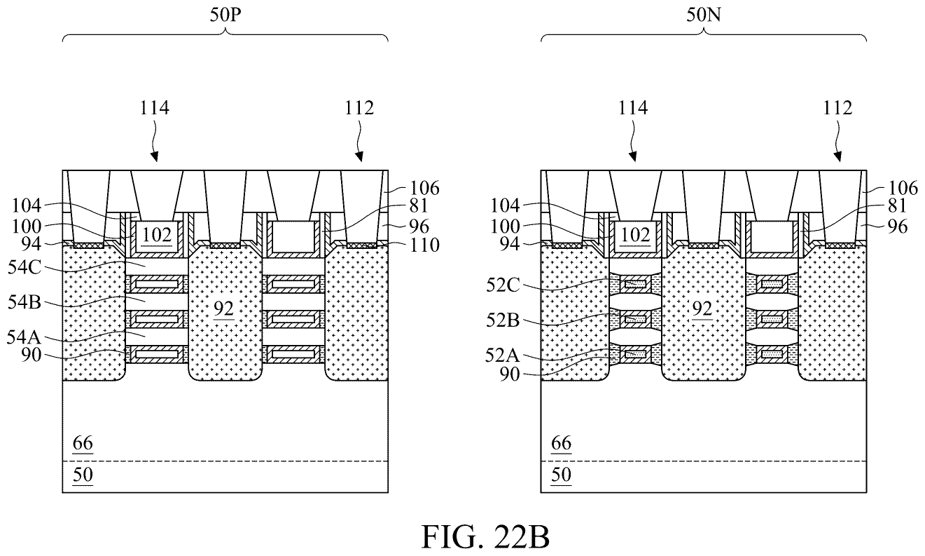

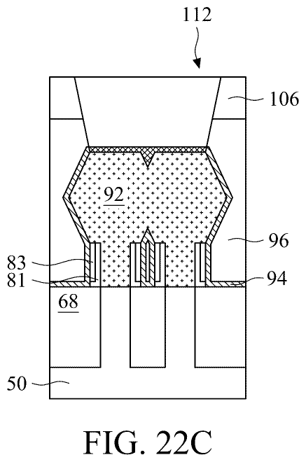

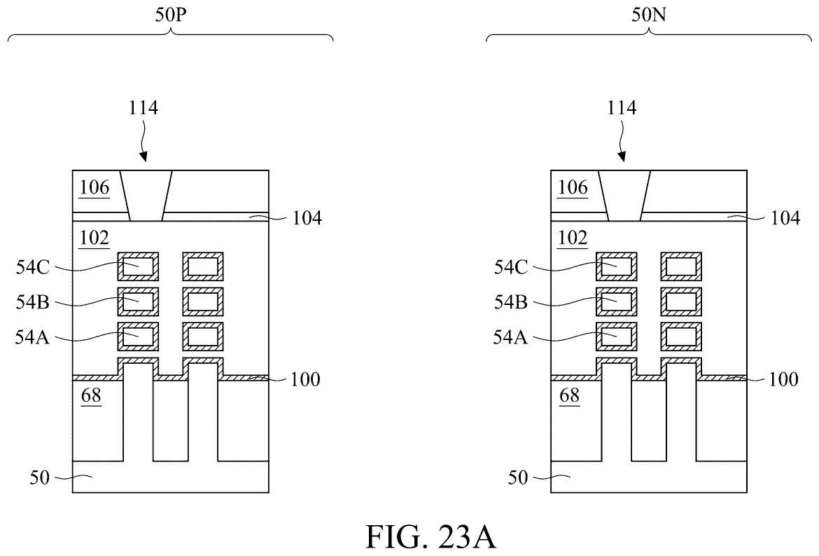

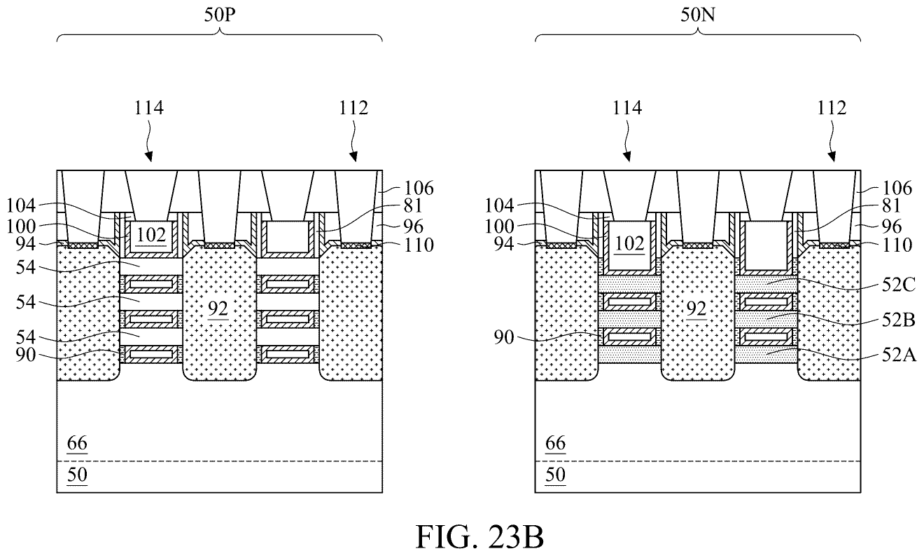

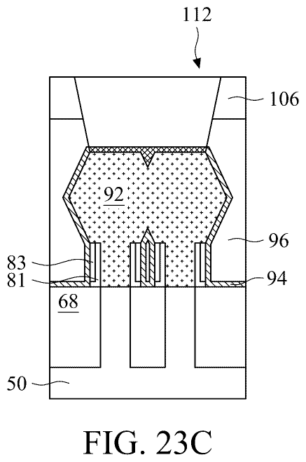

FIGS. 23A-23C illustrate cross-sectional views of a device according to some alternative embodiments. FIGS. 23A illustrates reference cross-section A-A′ illustrated in FIG. 1. FIG. 23B illustrates reference cross-section B-B′ illustrated in FIG. 1. FIG. 23C illustrates reference cross-section C-C′ illustrated in FIG. 1. In FIGS. 23A-23C, like reference numerals indicate like elements formed by like processes as the structure of FIGS. 22A-22C. However, in FIGS. 23A-C, channel regions in the n-type region 50N and the p-type region 50P comprise different materials. For example, the first nanostructures 52, which comprise silicon germanium, provide channel regions for n-type nano-FETs in the n-type region 50N. The structure of FIGS. 23A-C may be formed, for example, by removing the second nanostructures 54 from the devices in the n-type regions 50N and replacing the second nanostructures 54 with the gate electrodes 102. In such embodiments, materials of the channels and epitaxial source/drain regions 92 may be different in the n-type region 50N compared to the p-type region 50P as explained above.

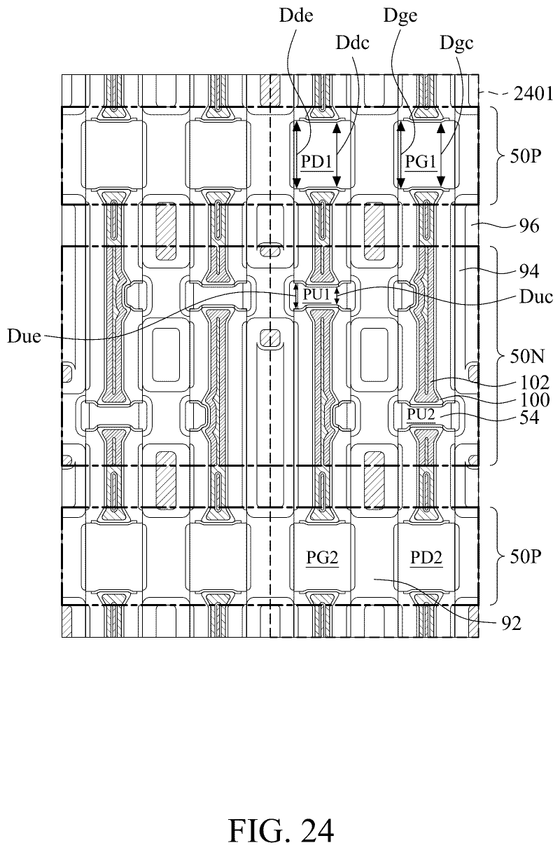

FIG. 24 illustrates a top down view of multiple SRAM devices 2401 (with one such device surrounded by the dashed line) utilizing the nanostructures described in FIGS. 2-23C. In a particular embodiment FIG. 24 illustrates a six transistor (6T) SRAM device which utilizes the pull-up transistors PU1 and PU2; the pull-down transistors PD1 and PD2; and the pass-gate transistors PG1 and PG2. In this embodiment the pull-up transistors PU1 and PU2 are NMOS devices within the n-type region 50N and the pull-down transistors PD1 and PD2 along with the pass-gas transistors PG1 and PG2 are PMOS devices located within the p-type region 50P. Additionally in this embodiment, the PMOS devices (e.g., the pull-down transistors PD1 and PD2 and the pass-gas transistors PG1 and PG2) are formed with the use of the disposable material 86 (e.g., the dummy oxide interposer) while the NMOS devices (e.g., the pull-up transistors PU1 and PU2) are formed without the use of the disposable material 86.

Because the pull-up transistors PU1 and PU2 are formed without the use of the disposable material 86, the second nanostructures 54 within the pull-up transistors PU1 and PU2 do not receive the protection from the presence of the disposable material 86. As such, the second nanostructures 54 in the n-type region 50N (e.g., within the NMOS pull-up devices PU1 and PU2) may have a smaller width than the second nanostructures 54 in the p-type regions 50P (e.g., the PMOS devices with the disposable material 86) because of the differences in etching process. For example, the second nanostructures 54 in the n-type region 50N (e.g., the NMOS pull-up devices PU1 and PU2) may be etched with a CERTAS etch while the second nanostructures 54 in the p-type region 50P (e.g., the PMOS devices with the disposable material 86) may be etched with a dilute hydrofluorice acid (dHF) etch. In particular, in some embodiments the pull-up transistors PU1 and PU2 may have a pull-up center distance D_{uc} and the pull-up transistors PU1 and PU2 may have a pull-up edge distance Dᵤₑ. A ratio of the pull-up edge distance Dᵤₑ and the pull-up center distance D_{uc} (e.g., Dᵤₑ/D_{uc}) is between about 1.05 and 1.5 and a difference between the pull-up edge distance Dᵤₑ and the pull-up center distance D_{uc} (e.g., Dᵤₑ−D_{uc}) is between about 2 nm and about 5 nm. However, any suitable distance may be utilized.

However, by using the disposable material 86 in the manufacture of the pull-down transistors PD1 and PD2 and the pass-gas transistors PG1 and PG2, the second nanostructures 54 within these devices are protected during the manufacturing process. As such, the second nanostructures 54 within these devices may have larger dimensions than the second nanostructures 54 within the pull-up transistors PU1 and PU2 as they are not damaged from subsequent processes. For example, the pull-down transistors PD1 and PD2 may have second nanostructures 54 with a pull-down center distance D_{dc} and may also have a pull-down edge distance D_{de}. Additionally, the pass-gate transistors PG1 and PG2 may have second nanostructures 54 with a pass-gate center distance D_{gc} and may also have a pass-gate edge distance D_{ge}. However, any suitable distance may be utilized.

In an embodiment a ratio of the pull-down edge distance D_{de} and pull-down center distance D_{dc} (e.g., D_{de}/D_{dc}) is greater than 1 and less than 1.05. Further, a ratio of the pass-gate edge distance D_{ge} and the pass-gate center distance D_{gc} (e.g., the D_{ge}/D_{gc}) is greater than 1 and less than 1.05. Also, a difference of the pull-down edge distance D_{de} and the pull-down center distance D_{dc} (e.g. D_{de}-D_{dc}) is greater than zero and less than 2.5 nm. However, any suitable dimensions may be utilized.

By utilizing the disposable material 86 in the manufacture of the transistors used to form the SRAM device 2401, the DOI process can help to decrease silicon loss of the sheets (e.g., the nanostructures 54) during the sheet formation process. As such, the disposable material 86 helps to increase the channel widths of at least some of the devices without increasing the overall oxide definition (OD) width, leading to an improvement in the current and boosting performance (e.g., lsat). In some particular embodiments the SRAM device 2401 may have an OD ratio (p-type OD width/n-type OD width) that is equal to 1 (for high-density devices) or is greater than 1 (for high-current devices), such as ratios of between about 1.5 and about 4.

Additionally, because the DOI process causes a larger improvement in PMOS devices than in NMOS devices, it is now feasible to form the pull-down transistors PD1 and PD2 and the pass gate transistors PG1 and PG2 as PMOS devices and to form the pull-up transistors PU1 and PU2 as NMOS devices. In such embodiments the alpha ratio (e.g., Isat_{PU}/Isat_{PG}) for the overall SRAM device 2401 can be reduced to less than 1, thereby improving the write margin. Further, the use of the DOI process also helps to reduce the capacitance between the PMOS pass gate transistors PG1 and PG2 and adjacent conductive lines, thereby increasing write speed.

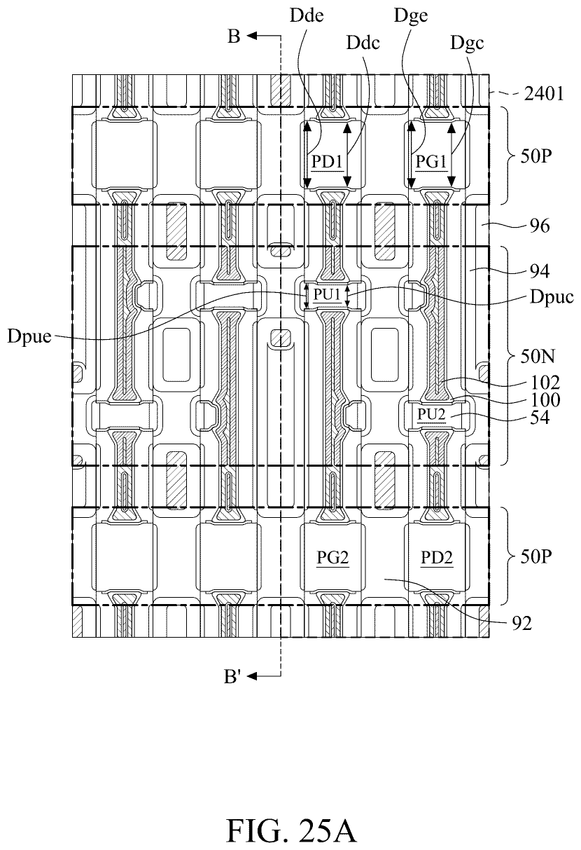

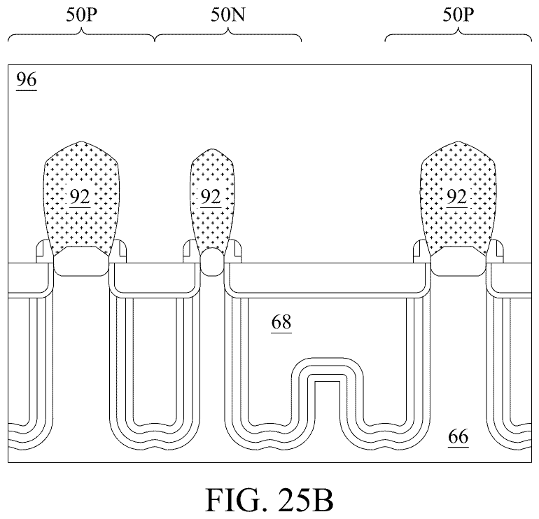

FIG. 25A illustrates another embodiment in which the disposable material 86 is utilized, the pull-down transistors PD1 and PD2 and the pass-gas transistors PG1 and PG2 are PMOS devices, and the pull-up transistors PU1 and PU2 are NMOS devices. In this embodiment, however, instead of using the disposable material 86 for only the pull-down transistors PD1 and PD2 and the pass-gas transistors PG1 and PG2 (and not for the pull-up transistors PU1 and PU2) as described above, the disposable material 86 is utilized in the manufacture of all of the transistors in the SRAM device 2401, including the pull-up transistors PU1 and PU2 as well. In this embodiment, the first nanostructures 52 are removed from both the p-type region 50P and the n-type region 50N, the disposable material 86 is formed within both the n-type region 50N and the p-type region 50P, where the disposable material 86 is used to protect the second nanostructures 54 within the p-type region 50P as well as the second nanostructures 54 within the n-type region 50N.

By forming all of the transistors within the SRAM devices 2401 with the disposable material 86, there is less material loss of the second nanostructures 54 in not just the pull-down transistors PD1 and PD2 and the pass-gas transistors PG1 and PG2 but also the pull-up transistors PU1 and PU2. For example, in this embodiment the pull-up transistors PU1 and PU2 may have a protected pull-up center distance D_{puc} and may have a protected pull-up edge distance Dₚᵤₑ. A ratio of the protected pull-up edge distance Dₚᵤₑ and the protected pull-up center distance D_{puc} (e.g., Dₚᵤₑ/D_{puc}) is between about 1 and about 1.05. However, any suitable dimensions may be utilized.

FIG. 25B illustrates a cross-sectional view of FIGS. 25A through line B-B′ in FIG. 25A. As can be seen in FIG. 25B, the epitaxial source/drain regions 92 are formed in the p-type regions 50P and the n-type regions 50N (along with a fin 66 that has been reduced in height). Additionally, the first ILD 96 is deposited over the epitaxial source/drain regions 92. However, any suitable structures may be utilized.

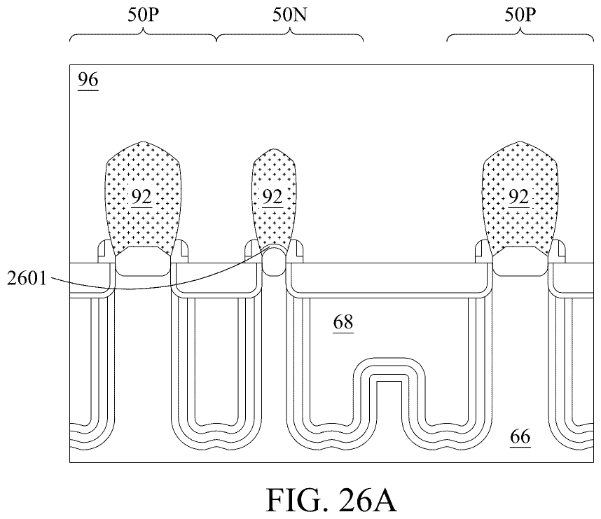

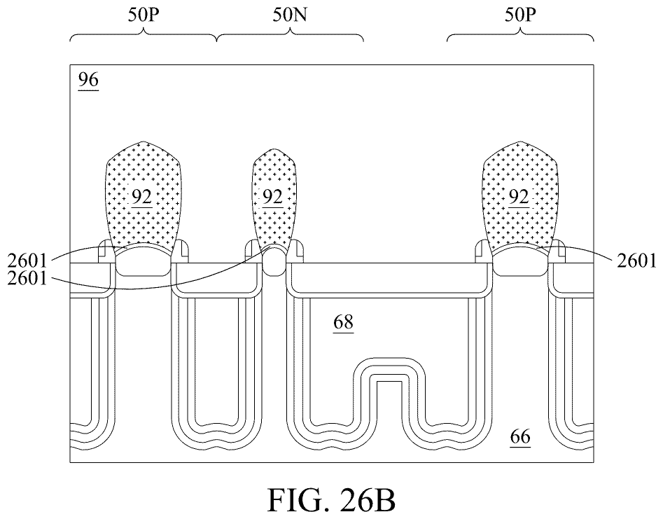

FIGS. 26A-26B illustrate embodiments in which floating bottom isolations (FBI) 2601 are additionally added in order to help improve and reduce cell capacitance. In the embodiment illustrated in FIG. 26A, the floating bottom isolation 2601 is formed after the first recesses 84 are formed in the fins 66 (see, e.g., FIG. 9A above) and prior to the formation of the epitaxial source/drain regions 92 (see, e.g., FIGS. 14A-14C). In the embodiment illustrated in FIG. 26A, the floating bottom isolation 2601 is formed only on the fins 66 located within the n-type region 50N, while the devices within the p-type region 50P are free from the floating bottom isolation 2601.

In an embodiment the floating bottom isolation 2601 is formed of an isolation material the helps to reduce the capacitance of the devices. For example, the floating bottom isolation 2601 may be formed using a method such as epitaxial growth. However, any suitable material and any suitable process of forming the floating bottom isolation 2601 may be utilized. Once the floating bottom isolation 2601 has been formed on the fins 66, a remainder of the process steps may be completed in order to form the SRAM device 2401.

FIG. 26B illustrates another embodiment in which the floating bottom isolation 2601 is utilized. In this embodiment, however, instead of forming the floating bottom isolation 2601 over only the fins 66 located within the n-type region 50N, the floating bottom isolation 2601 is formed on the fins 66 located within both the n-type region 50N and the p-type region 50P. In an embodiment the floating bottom isolations 2601 within each region may be formed simultaneously with each other, or else sequentially with each other. However, any suitable methods may be utilized.

With the use of the disposable material 86 for the PMOS devices, the floating bottom isolation 2601, which does have some negative impacts (e.g., lowering the strain of the epitaxial material), may be used with fewer of the negative impacts to the overall device. As such, the use of the floating bottom isolation 2601 may be used to help counteract undesired capacitance issues, such as the undesired capacitance between the transistors and, e.g., the bit line BL (see FIG. 1B). In a particular embodiment in which the floating bottom isolation 2601 is utilized for each device, the bit line capacitance can be improved by about 3%.

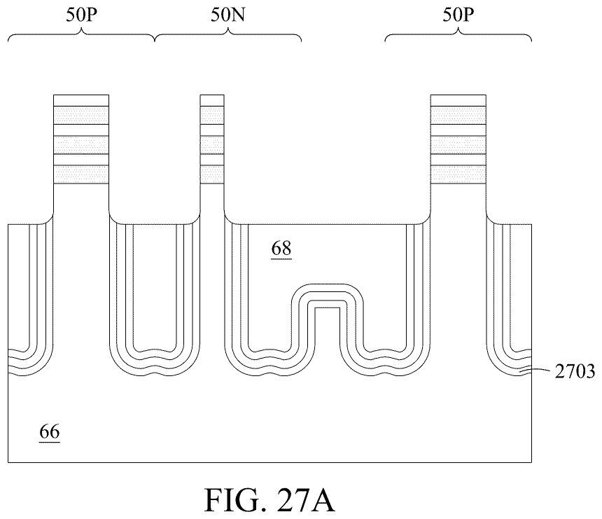

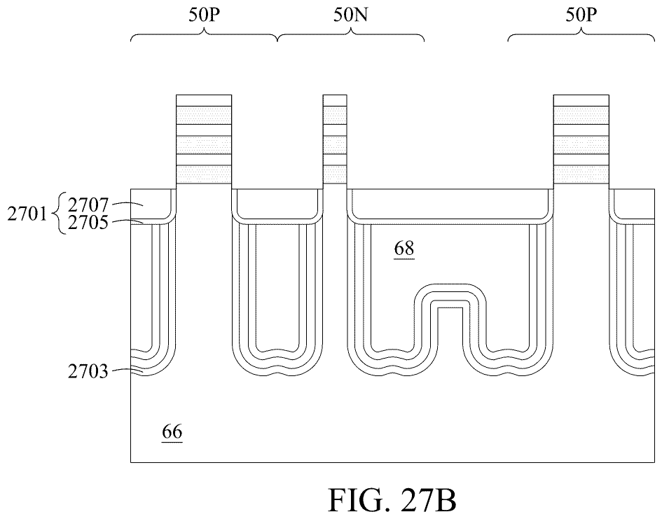

FIGS. 27A-27B illustrates another embodiment which not only utilizes the disposable material 86 but which also utilizes an STI cap layer 2701 (not illustrated in FIGS. 27A but illustrated in FIG. 27B) over the STI region 68. Looking first at FIG. 27A, the process may be initiated after the patterning of the fins 66 as described in FIG. 3 discussed above. Once the fins 66 have been formed, a cap 2703 may be formed between the fins 66 prior to formation of the STI regions 68. In an embodiment the cap 2703 may be a semiconductor material such as silicon formed using a deposition process such as chemical vapor deposition, physical vapor deposition, atomic layer deposition, epitaxial growth, combinations of these, or the like.

Once the cap 2703 has been formed, the STI region 68 may be formed over the cap 2703. In an embodiment the STI region 68 may be formed as described above with respect to FIG. 4, such as by depositing one or more layers of material (wherein multiple layers are illustrated in FIG. 27A but not illustrated in FIG. 4), planarized, and then recessed. However, any suitable processes may be utilized.

FIG. 27B illustrates that, once the STI region 68 has been formed, the STI cap layer 2701 is formed between the fins 66. In an embodiment the STI cap layer 2701 comprises a liner 2705 and a bulk material 2707. The liner 2705 may be a material such as silicon oxide deposited using a deposition process such as chemical vapor deposition, atomic layer deposition, physical vapor deposition, combinations of these, or the like. However, any suitable materials and processes may be utilized.

Once the liner 2705 has been formed, the bulk material 2707 may be formed. In an embodiment the bulk material 2707 may be a material such as silicon nitride formed using a deposition process such as chemical vapor deposition, atomic layer deposition, physical vapor deposition, combinations of these, or the like. However, any suitable materials and processes may be utilized.

Once the liner 2705 and the bulk material 2707 have been deposited, the liner 2705 and the bulk material 2707 may be planarized and then recessed. In an embodiment the liner 2705 and the bulk material 2707 may be planarized using a process such as chemical mechanical polishing and the materials may be recessed using one or more etching processes. However, any suitable processes may be utilized.

Once the liner 2705 and the bulk material 2707 have been recessed to form the STI cap layer 2701, a remainder of the processes discussed above may be utilized to form the devices. For example, the dummy gates 76 may be formed, the disposable material 86 may be formed and used to protect the second nanostructures 54, the epitaxial source/drain regions 92 may be formed, and the dummy gates 76 may be replaced. However, any suitable processes may be utilized.

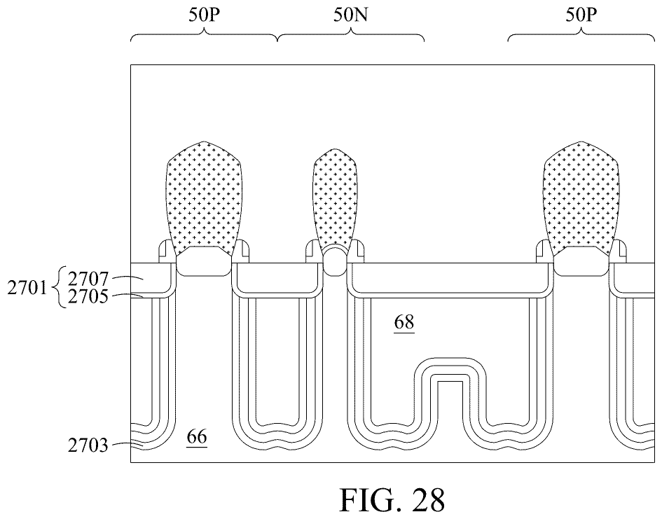

FIG. 28 illustrates yet another embodiment in which the STI cap layer 2701 is utilized. In this embodiment, in addition to the STI cap layer 2701 being formed, the floating bottom isolations 2601 are also formed along one or more of the PMOS devices and NMOS devices. Any suitable combination of STI cap layers 2701 and floating bottom isolations 2601 may be used.

Additionally, the various embodiments described of the STI cap layer 2701 and the floating bottom isolations 2601 may be used along with any of the embodiments described above with the usage of the disposable material 86. For example, the STI cap layer 2701 and/or the floating bottom isolations 2601 (on one or all of the fins 66) can be used with devices in which the disposable material 86 is used for just the PMOS devices, or with devices in which the disposable material 86 is used for the PMOS devices and the NMOS devices. All such combinations are fully intended to be included within the scope of the embodiments.

By utilizing the disposable material 86 in the manufacture of the transistors (and thereby replacing the SiGe with silicon oxide), there is a larger improvement in PMOS devices than in NMOS devices since the strain effect of SiGe on silicon is larger for NMOS than for PMOS devices. For example, the PMOS device lsat can be improved about between 15%-20% with the use of the disposable material 86 (through, e.g., PMOS stress release) and the NMOS device lsat can be improved between about 3% and about 5%, so that the Vts-lsat is now better than an NMOS device. This allows the pull-down transistors PD1 and PD2 and the pass-gate transistors PG1 and PG2 to be formed as PMOS devices while the pull-up transistors PU1 and PU2 may be formed as NMOS devices. As such, with the pull-down transistors PD1 and PD2 and the pass-gate transistors PG1 and PG2 being PMOS devices and the pull-up transistors PU1 and PU2 being NMOS devices, an alpha ratio (lsat_{PU}/lsat_{PG}) for the SRAM device may be less than 1, allowing for an improved SRAM write margin. Additionally, the use of the floating bottom isolation 2601 helps to improve the total capacitance between the various lines and the STI cap layers 2701 may be used to provide further protection during the manufacturing processes.

In an embodiment, a method of manufacturing a semiconductor device, the method including: forming a multi-layer stack over a substrate, the multi-layer stack comprising alternating layers of first semiconductor layers and second semiconductor layers; forming a first PMOS pull down transistor, the forming the first PMOS pull down transistor including: removing the first semiconductor layers in a first region of the substrate; forming a disposable material between the second semiconductor layers in the first region; forming source/drain regions adjacent the second semiconductor layers and the disposable material in the first region; and replacing the disposable material in the first region with a first metal gate structure; and forming a first NMOS pull up transistor, the forming the first NMOS pull up transistor comprising replacing the first semiconductor layers in a second region of the substrate with a second metal gate structure. In an embodiment the disposable material is selected from the group consisting of silicon oxide, silicon oxynitride, and aluminum oxide. In an embodiment the forming the first NMOS pull up transistor further includes: removing the first semiconductor layers; forming the disposable material between the second semiconductor layers in the second region; and replacing the disposable material in the second region with the second metal gate structure. In an embodiment during the forming the first NMOS pull up transistor the disposable material is not deposited between the second semiconductor layers in the second region. In an embodiment the forming the first PMOS pull down transistor further comprises forming a first floating bottom isolation in the first region prior to the forming the source/drain regions. In an embodiment the forming the first NMOS pull up transistor further comprises forming a second floating bottom isolation in the second region. In an embodiment the method further includes: forming an STI region; and forming an STI cap over the STI region.

In an embodiment, a method of manufacturing a semiconductor device, the method including: forming fins from a multi-layer stack of alternating layers of first semiconductor material and second semiconductor material, wherein a first fin is located in a first region and a second fin is located in a second region; replacing the first semiconductor material in the first fin with a dielectric material; forming a first source/drain region in physical contact with the second semiconductor material in the first fin; forming a second source/drain region in physical contact with the second semiconductor material in the second fin; replacing the dielectric material in the first fin with a first gate structure of a first PMOS pass gate transistor; and forming a second gate structure of a first NMOS pull up transistor around the second semiconductor material in the second fin. In an embodiment the forming the second gate structure includes: replacing the first semiconductor material in the second fin with the dielectric material; and replacing the dielectric material in the second fin with the second gate structure. In an embodiment the forming the second gate structure comprises replacing the first semiconductor material in the second fin with the second gate structure without forming the dielectric material within the second fin. In an embodiment the forming the first source/drain region comprises forming a first floating bottom isolation. In an embodiment the forming the second source/drain region comprises forming a second floating bottom isolation. In an embodiment the method further includes: depositing a first STI material between the fins; recessing the first STI material; depositing a silicon nitride cap over the first STI material; and recessing the silicon nitride cap. In an embodiment the first PMOS pass gate transistor and the first NMOS pull up transistor are part of a six transistor SRAM memory cell.

In an embodiment, a semiconductor device includes: a first pull up transistor and a second pull up transistor; a first pull down transistor and a second pull down transistor; a first pass gate transistor and a second pass gate transistor, wherein the first pass gate transistor comprises a first nanostructure with a first center width and wherein the first pull up transistor comprises a second nanostructure with a second center width less than the first center width. In an embodiment the first pass gate transistor comprises a first edge width and wherein a ratio of the first edge width and the first center width is between 1 and 1.05. In an embodiment the semiconductor device further includes a first inner spacer adjacent to the first nanostructure and a second inner spacer adjacent to the second nanostructure, wherein the first inner spacer has a different shape than the second inner spacer. In an embodiment the first inner spacer has a first germanium concentration and the second inner spacer has a second germanium concentration different from the first germanium concentration. In an embodiment the first pull up transistor comprises a floating bottom isolation. In an embodiment the first nanostructure has a smoother bottom surface than the second nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming a multi-layer stack over a substrate, the multi-layer stack comprising alternating layers of first semiconductor layers and second semiconductor layers;
forming a first PMOS pull down transistor, the forming the first PMOS pull down transistor comprising:
removing the first semiconductor layers in a first region of the substrate;
forming a disposable material between the second semiconductor layers in the first region;
forming source/drain regions adjacent the second semiconductor layers and the disposable material in the first region; and
replacing the disposable material in the first region with a first metal gate structure; and
forming a first NMOS pull up transistor, the forming the first NMOS pull up transistor comprising replacing the first semiconductor layers in a second region of the substrate with a second metal gate structure.

2. The method of claim 1, wherein the disposable material is selected from the group consisting of silicon oxide, silicon oxynitride, and aluminum oxide.

3. The method of claim 1, wherein the forming the first NMOS pull up transistor further comprises:
removing the first semiconductor layers;
forming the disposable material between the second semiconductor layers in the second region; and
replacing the disposable material in the second region with the second metal gate structure.

4. The method of claim 1, wherein during the forming the first NMOS pull up transistor the disposable material is not deposited between the second semiconductor layers in the second region.

5. The method of claim 1, wherein the forming the first PMOS pull down transistor further comprises forming a first floating bottom isolation in the first region prior to the forming the source/drain regions.

6. The method of claim 5, wherein the forming the first NMOS pull up transistor further comprises forming a second floating bottom isolation in the second region.

7. The method of claim 1, further comprising:
forming an STI region; and
forming an STI cap over the STI region.

8. A method of manufacturing a semiconductor device, the method comprising:
forming fins from a multi-layer stack of alternating layers of first semiconductor material and second semiconductor material, wherein a first fin is located in a first region and a second fin is located in a second region;
replacing the first semiconductor material in the first fin with a dielectric material;
forming a first source/drain region in physical contact with the second semiconductor material in the first fin;
forming a second source/drain region in physical contact with the second semiconductor material in the second fin;
replacing the dielectric material in the first fin with a first gate structure of a first PMOS pass gate transistor; and
forming a second gate structure of a first NMOS pull up transistor around the second semiconductor material in the second fin.

9. The method of claim 8, wherein the forming the second gate structure comprises:
replacing the first semiconductor material in the second fin with the dielectric material; and
replacing the dielectric material in the second fin with the second gate structure.

10. The method of claim 8, wherein the forming the second gate structure comprises replacing the first semiconductor material in the second fin with the second gate structure without forming the dielectric material within the second fin.

11. The method of claim 8, wherein the forming the first source/drain region comprises forming a first floating bottom isolation.

12. The method of claim 11, wherein the forming the second source/drain region comprises forming a second floating bottom isolation.

13. The method of claim 8, further comprising:
depositing a first STI material between the fins;
recessing the first STI material;
depositing a silicon nitride cap over the first STI material; and
recessing the silicon nitride cap.

14. The method of claim 8, wherein the first PMOS pass gate transistor and the first NMOS pull up transistor are part of a six transistor SRAM memory cell.

15. A semiconductor device comprising:
a first pull up transistor and a second pull up transistor;
a first pull down transistor and a second pull down transistor;
a first pass gate transistor and a second pass gate transistor, wherein the first pass gate transistor comprises a first nanostructure with a first center width and wherein the first pull up transistor comprises a second nanostructure with a second center width less than the first center width.

16. The device of claim 15, wherein the first pass gate transistor comprises a first edge width and wherein a ratio of the first edge width and the first center width is between 1 and 1.05.

17. The device of claim 15, further comprising a first inner spacer adjacent to the first nanostructure and a second inner spacer adjacent to the second nanostructure, wherein the first inner spacer has a different shape than the second inner spacer.

18. The device of claim 17, wherein the first inner spacer has a first germanium concentration and the second inner spacer has a second germanium concentration different from the first germanium concentration.

19. The device of claim 15, wherein the first pull up transistor comprises a floating bottom isolation.

20. The device of claim 15, wherein the first nanostructure has a smoother bottom surface than the second nanostructure.
